(19) United States
(12) Patent Application Publication
(10) Pub. No.: US 2008/0052566 A1
(43) Pub. Date: Feb. 28, 2008

(54) System and method for detecting routing problems

(76) Inventors: Paul N. Cashman, Alton (GB); Roderick G.C. Moore, Bournemouth (GB)

Correspondence Address: LAW OFFICES OF MICHAEL DRYJA, 1474 N COOPER RD #105-248, GILBERT, AZ, 85233, US

(21) Appl. No.: 11/766,572

(22) Filed: Jun. 21, 2007

(30) Foreign Application Priority Data
Jun. 24, 2006 (GB) 0612573.6

(51) Int. Cl. G01R 31/28

(52) U.S. Cl. 714/716

(57) ABSTRACT

A system includes an adapter and a string of switches having a head-of-string switch and a tail-of-string switch. The adapter is connected to the head-of-string switch. Each switch in the string is connected to an adjacent switch. The system further includes one or more devices connected to each respective switch. The system is arranged to periodically transmit a first signal from a first device connected to an end-of-string switch. The first signal passes through all of the switches in the string to a second device connected to the opposite end-of-string switch. A second signal is transmitted from the second device to the first device. In this way, routing problems in the switches can be detected. The first device is arranged to generate an error message, following a predefined period after transmitting the first signal, if the second signal is not received at the first device.

### RELATED APPLICATIONS

The present patent application claims priority to the previously filed United Kingdom patent application entitled “system and method for detecting routing problems,” filed on Jun. 24, 2006, and assigned serial no. 0612573.6.

### FIELD OF THE INVENTION

The present invention relates generally to a system including a string of switches, such as a switch loop subsystem, and to a method of operating such a system. More particularly, the invention relates to detecting routing problems in such systems.

### BACKGROUND OF THE INVENTION

In a non-switched Fiber Channel-Arbitrated Loop (FC-AL) disk system the fiber channel layer is configured as a loop. Any traffic sent from an adapter must traverse the whole loop successfully. This makes it easy to detect problems with the fiber channel loop as a command can be sent, and if the expected response is received then the loop must be intact. This is normally used in a dual adapter environment where one adapter will use a Small Computer System Interface (SCSI) transaction to another adapter in order to involve both the whole FC-AL, and also to ensure that both adapters are capable of opening connections and sending data on the FC-AL. This transaction is commonly called a ping.

In a switched FC-AL system, if the adapters are attached to the same switch, then the ping is only able to indicate if the one hop into and out of the first switch is functional. and gives no information about the state of the rest of the loop, which may contain several cascaded switches. The only information available is the fact that the adapters can arbitrate and gain access to the loop.

The only way, in such a system, that it is possible to tell if a loop has a problem routing traffic, is that a device in a pack attached to a switch that is located after the routing problem, fails to respond and gets a hung or lost command. These failures rely on the SCSI level timeouts to detect the problem which can be of the order of five seconds. The response to the timeout is often to log an error against the specific device rather than informing that there may be a switch/loop problem. This leads to potentially failing perfectly good drives, which in turn impacts availability of customer's data by removing redundant components unnecessarily and also impacts the cost of maintenance.

### SUMMARY OF THE INVENTION

The present invention relates generally to detecting routing problems. A system of an embodiment of the invention includes an adapter and a string of switches having a head-of-string switch and a tail-of-string switch. The adapter is connected to the head-of-string switch. Each switch in the string is connected to an adjacent switch. The system further includes one or more devices connected to each respective switch. The system is arranged to periodically transmit a first signal from a first device connected to an end-of-string switch. The first signal passes through all of the switches in the string to a second device connected to the opposite end-of-string switch. A second signal is transmitted from the second device to the first device. In this way, routing problems in the switches can be detected. The first device is arranged to generate an error message, following a predefined period after transmitting the first signal, if the second signal is not received at the first device.

### BRIEF DESCRIPTION OF THE DRAWINGS

The drawings referenced herein form a part of the specification. Features shown in the drawing are meant as illustrative of only some embodiments of the invention, and not of all embodiments of the invention, unless otherwise explicitly indicated, and implications to the contrary are otherwise not to be made.

FIG. 1 is a schematic diagram of a system including a switched FC-AL loop, according to an embodiment of the invention.

FIG. 2 is schematic diagram of the system of FIG. 1, showing a conventional ping traversing components in the system, according to an embodiment of the invention.

FIG. 3 is schematic diagram of the system of FIG. 1, showing signals traversing components in the system, according to an embodiment of the invention.

FIG. 4 is a flowchart of a method of operating the system of FIG. 1, according to an embodiment of the invention.

### DETAILED DESCRIPTION OF THE INVENTION

In the following detailed description of exemplary embodiments of the invention, reference is made to the accompanying drawings that form a part hereof, and in which is shown by way of illustration specific exemplary embodiments in which the invention may be practiced. These embodiments are described in sufficient detail to enable those skilled in the art to practice the invention. Other embodiments may be utilized, and logical, mechanical, and other changes may be made without departing from the spirit or scope of the present invention. The following detailed description is, therefore, not to be taken in a limiting sense, and the scope of the present invention is defined only by the appended claims.

Overview

According to a first aspect of the present invention, a system is provided that includes an adapter, and a string of switches including a head-of-string switch and a tail-of-string switch. The adapter is connected to the head-of-string switch. Each switch in the string is connected to an adjacent switch. The system also includes one or more devices connected to each respective switch, where the system is arranged to periodically transmit a first signal from a first device connected to an end-of-string switch. The first signal passes through all of the switches in the string to a second device connected to the opposite end-of-string switch. A second signal is transmitted from the second device to the first device.

According to a second aspect of the present invention, a method of operating a system is provided. The system includes an adapter, and a string of switches including a head-of-string switch and a tail-of-string switch. The adapter is connected to the head-of-string switch. Each switch in the string is connected to an adjacent switch. The system also includes one or more devices connected to each respective switch. The method periodically transmits a first signal from a first device connected to an end-of-string switch. The first signal passes through all of the switches in the string to a second device connected to the opposite end-of-string switch. The method transmits a second signal from the second device to the first device.

Owing to embodiments of the invention, it is possible to detect any errors in a loop formed of a string of switches, wherever that error is occurring. The solution to the problem of how to detect an error in a switched system is to use a transaction that involves opening a connection and sending a defined packet/message, the response to which is to open a new connection to send a reply. The transaction can take place between each adapter and a device attached to the last switch in a cascade. This new ping continues to act as a dead man's handle on the adapter.

In a first embodiment, the first device is connected to the tail-of-string switch and the second device is the adapter. In a second embodiment, the first device is the adapter and the second device is connected to the tail-of-string switch. In order for the signal to travel through all of the switches in the system and for a response signal to travel back to the generator of the signal (the first device), either the adapter connected to the head-of-string switch or a device connected to the tail-of-string switch is the originator of the first signal. A device connected to the switch at the opposite end of string is the responder with the second signal.

Advantageously, the first device is arranged to generate an error message, following a predefined period after transmitting the first signal, if the second signal is not received at the first device. By transmitting the first signal and the waiting for a defined period of time for the reply to come back, the generator of the first signal can indicate that an error has occurred if, after the time period has elapsed, no response signal has been received. This allows constant verification on the operation of the switched loop system to be in place, which will detect any malfunction in the loop very quickly.

In one embodiment, the system further includes a second adapter, where the system is further arranged to transmit a third signal. The third signal passes through all of the switches in the string. A fourth signal is transmitted back to the originator of the third signal, where the second adapter is the originator of the third signal or the recipient of the third signal. If there is a second adapter, which is connected to the same switch as the first adapter (usually the head-of-string switch), then the communication route to and from that second adapter also may be periodically checked to ensure that all possible transmission routes within the system are working correctly.

The second signal can include an acknowledgement of the first signal. This is a simple embodiment of the error-checking method, in which the first signal is sent, for example, from a device connected to the tail-of-string switch to an adapter connected to the head-of-string switch, and the adapter replies with a simple acknowledgement of receipt of the first signal. Advantageously, the system can include one or more switches in-between the head-of-string switch and the tail-of-string switch of the string of switches. In at least some embodiments of the system, the loop includes a string of multiple switches, with one or more switches lying between the head-of-string switch and the tail-of-string switch.

A computer-readable medium of an embodiment of the invention has one or more computer programs stored thereon to perform a method for operating a system. The computer-readable medium may be a recordable data storage medium, or another type of tangible computer-readable medium. The system includes an adapter and a string of switches having a head-of-string switch and a tail-of-string switch. The adapter is connected to the head-of-string switch, and each switch in the string is connected to an adjacent switch. The system also includes one or more devices connected to each respective switch. The method periodically transmits a first signal from a first device connected to an end-of-string switch. The first signal passes through all of the switches in the string to a second device connected to the opposite end-of-string switch. The method also transmits a second signal from the second device to the first device.

### DESCRIPTION OF THE DRAWINGS

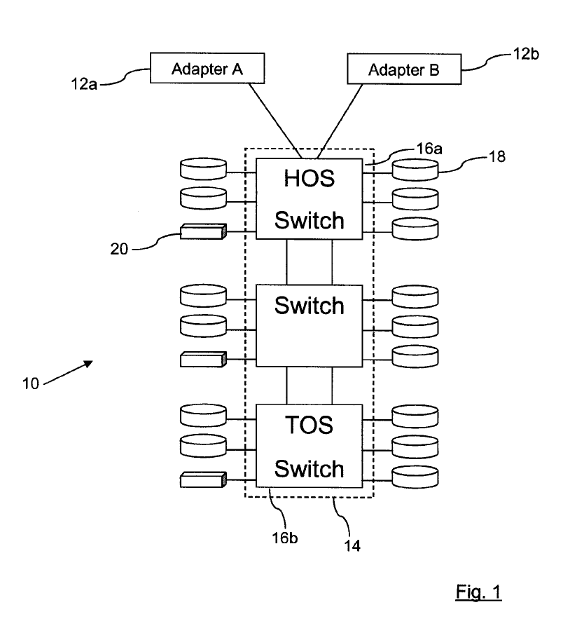

FIG. 1 shows a system 10 having two adapters 12a and 12b, and a string 14 of switches 16, according to an embodiment of the invention. The string 14 of switches 16 includes a head-of-string switch 16a and a tail-of-string switch 16b. The two adapters 12a and 12b are connected to the head-of-string switch 16a, and each switch 16 in the string 14 is connected to an adjacent switch 16. The string 14 of switches 16 forms a communication loop, with two communication channels joining each switch 16 to each and all adjacent switches 16. One or more switches 16 can be located in-between the head-of-string switch 16a and the tail-of-string switch 16b of the string 14 of switches 16. In the example of FIG. 1, a single intervening switch 16 is shown.

A number of devices are connected to each respective switch 16, such as Disk Drive Modules (DDMs) 18 and an SCSI Enclosure Services Device (SES) 20. Each switch 16 is shown in FIG. 1 as being configured in the same way, with five storage disks 18 and a single SES 20 being connected to each switch 16. However, the configuration and type of devices connected to a switch 16 is a design decision, being user configurable and does not affect the operation of the error testing method that is used in testing the system 10.

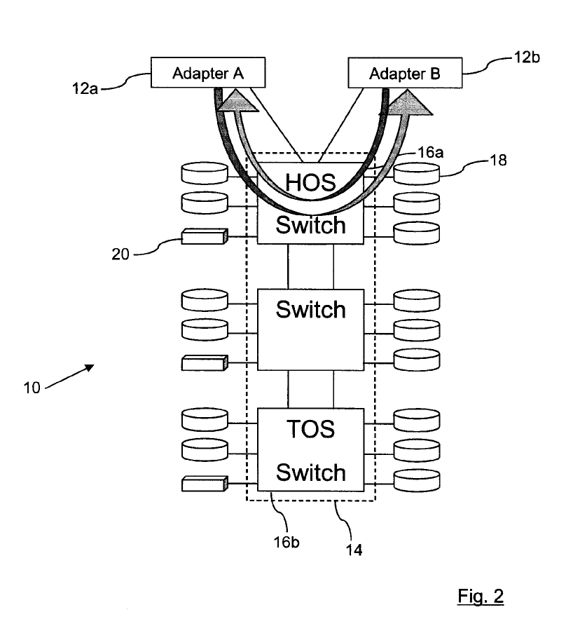

FIG. 2 shows the system of FIG. 1, according to an embodiment of the invention. In FIG. 2, a conventional ping command is routed between the two adapters 12. A command is sent from the first adapter 12a to the second adapter 12b, and a response is received back by the first adapter 12a from the second adapter 12b. The effectiveness of the either of the bottom two switches 16 is not tested by this signaling arrangement, as no data traffic passes through either the tail-of-string switch 16b nor through the switch 16 that is intermediate the head-of-string switch 16a and the tail-of-string switch 16b. The routing of data around this network cannot be assumed to be error-free.

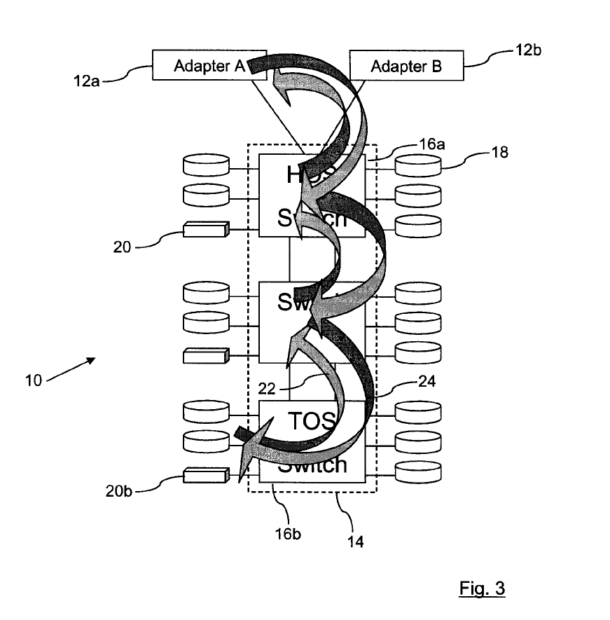

FIG. 3 shows how the system 10 operates, according to an embodiment of the invention. A specific signaling is used to detect any routing problems within the string 14 of switches 16. The system 10 is arranged to periodically transmit a first signal 22 from a first device (in this case the SES 20b) which is connected to an end-of-string switch (the tail switch 16b), the first signal 22 passing through all of the switches 16 in the string 14 to a second device (in this case the adapter 12a) connected to the opposite end-of-string switch (the head switch 16a). The adapter 12a transmits a second signal 24 back to the SES 20b. The second signal 24 comprises an acknowledgement of the first signal 22.

In the embodiment of FIG. 3, the first device (SES 20b), which is starting the communication through the string 14, is connected to the tail-of-string switch 16b and the device that is receiving the communication is the adapter 12b. An alternative to this arrangement is for the adapter 12a to start the communication to the SES 20b, which is connected to the tail-of-string switch 16b. In either case, a device that is connected to an end-of-string switch 16a or 16b is used to send a signal to a device connected to the opposite end-of-string switch 16a or 16b, that signal traversing all of the switches 16 in the string 14. The receiving device sends back a signal to the first device acknowledging receipt of the first signal.

The adapter 12a/b is arranged to generate an error message if the transmission of the first signal and the receipt of the second signal (or, the transmission of the second signal and the receipt of the first signal) fail within a predefined period. This allows a constant check, or verification, of the operation of the system 10, which will very quickly detect any malfunction in the string 14 of switches 16.

In FIG. 3, traffic is only shown to and from a single adapter 12a. If there is more than one adapter 12, then there would be a mirror to each of the other adapters 12 to enable testing of all possible routes within the system 10. In this situation, the system 10 is further arranged to transmit a third signal, the third signal passing through all of the switches 16 in the string 14, and to transmit a fourth signal back to the originator of the third signal. The second adapter 12b is either the originator of the third signal or the recipient of the third signal, in the same way as the adapter 12a is either the originator or the recipient of the first signal 22.

The transmission of the signals through the system 10, as described above, provides a solution to the problem of maintaining a check on the integrity of the system 10.

In a system that is based upon a protocol such as FC-AL, the first signal 22 can be an SCSI transaction that involves the components in the last attached enclosure (cascaded switch). This transaction can take a variety of forms. One such form is to send the first signal to the SES node, should it have an FC-AL port. This is not suitable for enclosures that use Enclosure Services Interface (ESI) via a Disk Drive Module (DDM) as there is no SES node directly on the FC-AL. Hence, another method is to identify a DDM in the last switch 16 and to use that FC-AL port instead. Each adapter 12 would need to start a transaction, in turn, in order to utilize each possible trunk of the switched network. Also, this is done on each FC-AL.

The alternative solution, to that discussed above, is to use an FC-AL attached SES device 20b to instigate the signal to each adapter 12. The SES 20b could use a low level FC-AL frame for this purpose, e.g. Extended Link Services (ELS) frames. In this example the SES 20b in the bottom enclosure will initiate a State Change Notification ELS Frame (SCN) frame 22 every N seconds. (The SCN Frame is used in this example as it is an implemented FC-AL frame which is now obsolete in FC-AL specification).

This SCN frame 22 in this embodiment contains an adapter-specific payload that can be parsed and detected as an SES ping. The receipt of the ping 22 in the adapter 12 can be used to retrigger a dead mans handle. After loop initialization has completed, the SES 20b should initiate an SCN ping 22 when possible and from this time must issue a SCN ping 22 at the specified frequency.

If the adapter 12 does not see a ping 22 on a certain loop within a timeout period, after initial receipt, then the device is arranged to log the detection of a potential loop error and follow error recovery procedures. Each SES 20b in the tail-of-string enclosure is arranged to send a ping 22 on each loop to each adapter 12, thus all loops are tested for routing ability from the bottom enclosure up to each adapter 12.

On receipt of the ping the adapter 12 is arranged to send an acknowledge 24 (Ack) back to the tail-of-string SES 20b. This then tests the routing back down to the tail-of-string switch 16b. If the SES 20b does not receive an expected Ack 24 it will timeout sending the next ping 22 and thus the adapter 12 will detect that a problem exists on this loop/route.

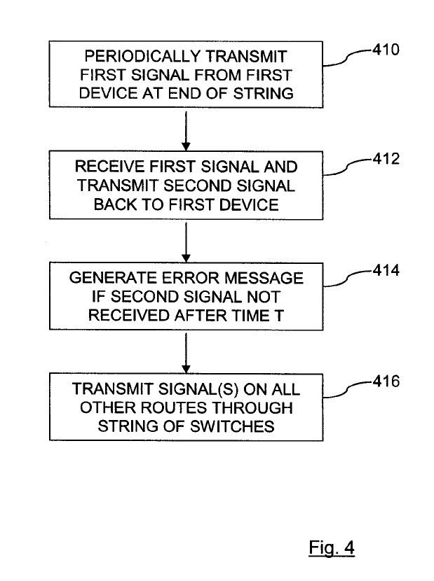

FIG. 4 shows a method that summarizes operation of the system 10 of FIG. 1, according to an embodiment of the invention. The first part 410 is periodically to transmit the signal 22 from a first device connected to one end of the string 14 of switches 16. This signal is then received at a second device connected to the opposite end of the string 14 of switches 16, which transmits back to the first device a second signal 24 (part 412). At part 414, an error message is triggered, if that second signal is not received by the first device, which started the process, within a predefined time period T. At part 416, the process is repeated for the other routes in the string 14 of switches 16, ensuring, for example, if there is more than one adapter 12 connected to an end-of-string switch that all the adapters 12 are queried in turn. This ensures that any and all routing problems in the string of switches are detected within a very short period of any error occurring.

It is finally noted that, although specific embodiments have been illustrated and described herein, it will be appreciated by those of ordinary skill in the art that any arrangement calculated to achieve the same purpose may be substituted for the specific embodiments shown. This application is thus intended to cover any adaptations or variations of embodiments of the present invention. Therefore, it is manifestly intended that this invention be limited only by the claims and equivalents thereof

What is claimed is:

1. A system comprising:
an adapter;
a string of switches comprising a head-of-string switch and a tail-of-string switch, the adapter connected to the head-of-string switch, each switch in the string connected to an adjacent switch; and,
one or more devices connected to each respective switch,
wherein the system is arranged to periodically transmit a first signal from a first device connected to an end-of-string switch, the first signal passing through all of the switches in the string to a second device connected to the opposite end-of-string switch and to transmit a second signal from the second device to the first device.

2. The system of claim 1, wherein the first device is connected to the tail-of-string switch and the second device is the adapter.

3. The system of claim 1, wherein the first device is the adapter and the second device is connected to the tail-of-string switch.

4. The system of claim 1, wherein the first device is arranged to generate an error message, following a predefined period after transmitting the first signal, if the second signal is not received at the first device.

5. The system of claim 1, further comprising a second adapter, wherein the system is further arranged to transmit a third signal, the third signal passing through all of the switches in the string, and to transmit a fourth signal back to the originator of the third signal, the second adapter being the originator of the third signal or the recipient of the third signal.

6. The system of claim 1, wherein the second signal comprises an acknowledgement of the first signal.

7. The system of claim 1, further comprising one or more switches in-between the head-of-string switch and the tail-of-string switch of the string of switches.

8. A method for operating a system, the system comprising an adapter, a string of switches comprising a head-of-string switch and a tail-of-string switch, the adapter connected to the head-of-string switch, each switch in the string connected to an adjacent switch, and one or more devices connected to each respective switch, the method comprising:
periodically transmitting a first signal from a first device connected to an end-of-string switch, the first signal passing through all of the switches in the string to a second device connected to the opposite end-of-string switch; and,
transmitting a second signal from the second device to the first device.

9. The method of claim 8, wherein the first device is connected to the tail-of-string switch and the second device is the adapter.

10. The method of claim 8, wherein the first device is the adapter and the second device is connected to the tail-of-string switch.

11. The method of claim 8, further comprising generating an error message at the first device, following a predefined period after transmitting the first signal, if the second signal is not received at the first device.

12. The method of claim 8, wherein the system further comprises a second adapter, and wherein the method further comprises transmitting a third signal, the third signal passing through all of the switches in the string, and transmitting a fourth signal back to the originator of the third signal, the second adapter being the originator of the third signal or the recipient of the third signal.

13. The method of claim 8, wherein the second signal comprises an acknowledgement of the first signal.

14. The method of claim 8, wherein the system further comprises one or more switches in-between the head-of-string switch and the tail-of-string switch of the string of switches.

15. A computer-readable medium having one or more computer programs to perform a method for operating a system, the system comprising an adapter, a string of switches comprising a head-of-string switch and a tail-of-string switch, the adapter connected to the head-of-string switch, each switch in the string connected to an adjacent switch, and one or more devices connected to each respective switch, the method comprising:
periodically transmitting a first signal from a first device connected to an end-of-string switch, the first signal passing through all of the switches in the string to a second device connected to the opposite end-of-string switch; and,
transmitting a second signal from the second device to the first device.

16. The computer-readable medium of claim 15, wherein the first device is connected to the tail-of-string switch and the second device is the adapter.

17. The computer-readable medium of claim 15, wherein the first device is the adapter and the second device is connected to the tail-of-string switch.

18. The computer-readable medium of claim 15, further comprising generating an error message at the first device, following a predefined period after transmitting the first signal, if the second signal is not received at the first device.

19. The computer-readable medium of claim 15, wherein the system further comprises a second adapter, and wherein the method further comprises transmitting a third signal, the third signal passing through all of the switches in the string, and transmitting a fourth signal back to the originator of the third signal, the second adapter being the originator of the third signal or the recipient of the third signal.

20. The computer-readable medium of claim 15, wherein the system further comprises one or more switches in-between the head-of-string switch and the tail-of-string switch of the string of switches.
